(19) United States
(12) Patent Application Publication
(10) Pub. No.: US 2010/0195396 A1
(43) Pub. Date: Aug. 5, 2010

(54) SEMICONDUCTOR MEMORY DEVICE AND SELF-TEST METHOD OF THE SAME

(76) Inventor: Tsutomu HIGUCHI, Kamakura-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/698,576

(22) Filed: Feb. 2, 2010

(30) Foreign Application Priority Data
Feb. 3, 2009 (JP) 2009-022665

(51) Int. Cl. G11C 16/02; G11C 29/00; G11C 7/10

(52) U.S. Cl. 365/185.17; 365/201; 365/189.05

(57) ABSTRACT

A semiconductor memory device includes a main memory includes a nonvolatile memory, and a buffer which stores input/output data of the nonvolatile memory, a buffer unit of the main memory, the buffer unit includes a volatile memory, a self-test interface includes a data input/output pin, and a controller which controls the main memory and the buffer unit. The controller at least stores data in the buffer from the self-test interface via the data input/output pin.

### CROSS-REFERENCE TO RELATED APPLICATIONS

This application is based upon and claims the benefit of priority from prior Japanese Patent Application No. 2009-022665, filed Feb. 3, 2009, the entire contents of which are incorporated herein by reference.

### BACKGROUND OF THE INVENTION

1. Field of the Invention

The present invention relates to a semiconductor memory device and a self-test method of the same.

2. Description of the Related Art

One NAND (registered trademark) is an example of a semiconductor memory device obtained by integrating a plurality of kinds of memories on one chip (e.g., Jpn. Pat. Appln. KOKAI Publication No. 2006-286179). This OneNAND is obtained by integrating a NAND flash memory as a main memory and an SRAM or DRAM as a buffer on one chip. To perform data transfer and the like between the NAND flash memory and the SRAM, a controller incorporating a state machine controls the semiconductor memory device.

### BRIEF SUMMARY OF THE INVENTION

According to an aspect of the present invention, there is provided a semiconductor memory device comprising: a main memory comprising a nonvolatile memory, and a buffer which stores input/output data of the nonvolatile memory; a buffer unit of the main memory, the buffer unit comprising a volatile memory; a self-test interface comprising a data input/output pin; and a controller which controls the main memory and the buffer unit, wherein the controller stores data in the buffer from the self-test interface via the data input/output pin, writes the stored data of the buffer in the volatile memory, stores the data read out from the volatile memory in the buffer, and reads out the stored data of the buffer from the self-test interface, and performs determination.

According to another aspect of the present invention, there is provided a self-test method of a semiconductor memory device, comprising: storing data in a buffer from a self-test interface via a data input/output pin; writing the stored data of the buffer in a volatile memory; storing the data read out from the volatile memory in the buffer; and reading out the stored data of the buffer from the self-test interface, and performing determination.

### BRIEF DESCRIPTION OF THE SEVERAL VIEWS OF THE DRAWING

FIG. 1 is a block diagram showing an example of the overall configuration of a semiconductor memory device according to the first embodiment of the present invention;

FIG. 2 is an equivalent circuit diagram showing blocks forming a NAND memory cell array shown in FIG. 1;

FIG. 3 is a flowchart showing the self-test operation of the semiconductor memory device according to the first embodiment;

FIG. 4 is a block diagram showing a self-test interface and scan path circuit of a semiconductor memory device according to the second embodiment;

FIG. 5 is a timing chart for explaining a scan-in mode of the semiconductor memory device according to the second embodiment;

FIG. 6 is a timing chart for explaining a scan-out mode of the semiconductor memory device according to the second embodiment; and

FIG. 7 is a view showing a configuration example of a semiconductor memory device according to a comparative example.

### DETAILED DESCRIPTION OF THE INVENTION

In the semiconductor memory device disclosed in the above-mentioned reference (Jpn. Pat. Appln. KOKAI Publication No. 2006-286179), for example, it is sometimes difficult to perform function tests on the SRAM or logic circuit and the NAND flash memory by using a common tester or testing step. In this case, different testing environments must separately be constructed for the SRAM or logic circuit and the NAND flash memory. This is disadvantageous in reducing the test cost.

Accordingly, embodiments of the present invention will be explained below with reference to the accompanying drawing. Note that in the following explanation, the same reference numerals denote the same parts throughout the drawing.

### First Embodiment

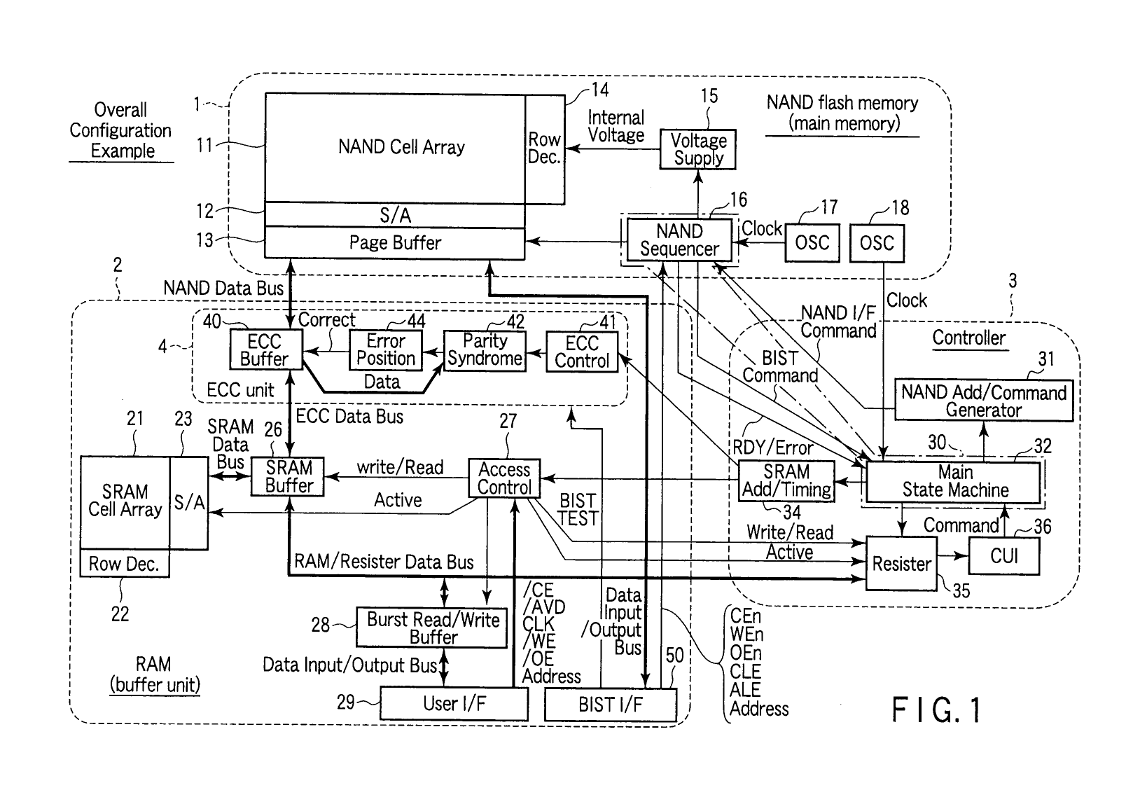

A semiconductor memory device and a self-test method of the same according to the first embodiment of the present invention will be explained below with reference to FIGS. 1 to 3.

### 1. Configuration Example

### 1-1. Example of Overall Configuration

First, an example of the overall configuration of the semiconductor memory device according to the first embodiment will be explained with reference to FIG. 1.

As shown in FIG. 1, the semiconductor memory device according to this embodiment is obtained by integrating a NAND flash memory (main memory) 1 as a main memory, an SRAM 2 as a buffer unit, and a controller 3 on one chip.

### Arrangement of NAND Flash Memory (Main Memory) 1

The NAND flash memory 1 includes a memory cell array 11, a sense amplifier 12, a page buffer 13, a row decoder 14, a voltage supply circuit 15, a NAND sequencer (first controller) 16, and oscillators 17 and 18.

The NAND memory cell array (NAND Cell Array) 11 is a memory cell array forming the memory area of the NAND flash memory 1, and includes a plurality of blocks (BLOCKs) (to be described later). Each block includes a plurality of memory cells arranged in a matrix at the intersections of bit lines and word lines.

Each of the plurality of memory cells has a stacked structure (not shown) including a tunnel insulating film, charge storage layer (floating electrode), inter-gate insulating film, and control electrode sequentially stacked on a semiconductor substrate. Each memory cell can hold, e.g., one-bit data in accordance with the change in threshold voltage corresponding to the amount of electrons injected into the floating gate. Note that each memory cell may also hold multilevel data having two or more bits by subdividing the control of the threshold voltage. Each memory cell may also have a MONOS (Metal Oxide Nitride Oxide Silicon) structure in which electrons are trapped in the nitride film.

The sense amplifier 12 simultaneously reads out data of one page from the memory cell array 11. A page (PAGE) is a unit in which data are collectively written or from which data are collectively read out in the NAND flash memory 11. For example, a plurality of memory cells connected to the same word line form one page. Details of the page will be described later.

The page buffer (Page Buffer) 13 temporarily stores readout data or write data of one page under the control of the sequencer 16. That is, the page buffer 13 temporarily holds data of one page read out from the memory cell array 11 in a read operation, and temporarily holds data of one page to be written in the memory cell array 11 in a write operation.

The row decoder (Row Dec.) 14 selects a word line of the memory cell array 11. The row decoder 14 also applies voltages necessary for, e.g., read, write, and erase to word lines.

The voltage supply circuit (Voltage Supply) 15 generates internal voltages (Internal Voltages) required for, e.g., read, write, and erase, and supplies the generated voltages to, e.g., the row decoder 14, under the control of the sequencer 16.

The NAND sequencer (NAND Sequencer) 16 receives a command signal (NAND I/F Command) issued from a NAND address/command generator (NAND Add/Command Generator) 31 to the NAND flash memory 1, and controls the whole of the NAND flash memory 1, e.g., write, read, and erase to the NAND flash memory 1. Note that the NAND sequencer 16 functions, together with a main state machine 32 (to be described later), as a controller 30 of the entire system of this semiconductor memory device.

Also, in a self-test (to be described later) including both (i) a test of write and read with respect to an SRAM memory cell array 21 and (ii) a test of data transfer between the page buffer 13 and the SRAM memory cell array 21, the NAND sequencer 16 can issue a BIST test command signal to the main state machine 32 of the controller 3. This BIST test command signal makes it possible to control those circuit operations in the semiconductor memory device, which are required for the self-test including both (i) the test of write and read with respect to the SRAM memory cell array 21 and (ii) the test of data transfer between the page buffer 13 and the SRAM memory cell array 21.

The oscillator (OSC) 17 generates an internal clock (Clock) for the internal control of the NAND sequencer 16.

The oscillator (OSC) 18 generates an internal clock (Clock) for the internal control of the main state machine 32.

### Arrangement of RAM (Buffer Unit) 2

The RAM 2 includes the SRAM memory cell array 21, a row decoder 22, a sense amplifier 23, an SRAM buffer 26, an access controller 27, a burst read/write buffer 28, a user interface 29, a self-test interface 50, and an ECC unit 4.

The SRAM memory cell array (SRAM Cell Array) 21 is used as a buffer for temporarily holding write data to be programmed in the NAND flash memory 1 and readout data loaded from the NAND flash memory 1, and exchanging the data with an external host apparatus. The SRAM memory cell array 21 includes a plurality of memory cells (SRAM cells) arranged in a matrix at the intersections of word lines and bit line pairs.

The row decoder (Row Dec.) 22 selects a word line of the SRAM memory cell array (SRAM Cell Array) 21.

The sense amplifier (S/A) 23 senses and amplifies data read out from an SRAM cell to a bit line. The sense amplifier 23 also functions as a load when writing the internal data of the SRAM buffer 26 in an SRAM cell.

The SRAM buffer (SRAM Buffer) 26 temporarily stores data when performing data read or write with respect to the SRAM memory cell array (SRAM Cell Array) 21.

The access controller (Access Controller) 27 receives an address and control signal input from the user interface (User I/F) 29, and performs control necessary for each internal circuit.

The burst read/write buffer (Burst Read/Write Buffer) 28 temporarily saves data for data read or write.

The user interface (User I/F) 29 of this embodiment supports the interface standards as in a NOR flash memory. The user interface 29 exchanges addresses, control signals, and data with the external host apparatus. Examples of the control signals are a chip enable signal (CEn) for activating the whole semiconductor memory device, an address valid signal (AVDn) for latching an address, a burst read clock (CLK), a write enable signal (WEn) for activating a write operation, and an output enable signal (OEn) for activating the outputting of data to the outside.

The self-test interface (BIST I/F) 50 includes a serial data input/output pin (SIO) (to be described later). In a self-test (BIST: Built In Self Test) to be conducted on the NAND flash memory 1 by using only a small number of test pins during a wafer probing test, the self-test interface 50 receives addresses and control signals from the page buffer 13 and NAND sequencer 16, and exchanges data with them.

This embodiment is configured to be able to execute the self-test including both (i) the test of write and read with respect to the SRAM memory cell array 21 and (ii) the test of data transfer between the page buffer 13 and the SRAM memory cell array 21, in addition to a self-test such as the test of write or read with respect to the NAND flash memory 1, in the test step of the wafer probing test conducted by the self-test interface 50. Note that as will be explained later in the second embodiment, the self-test interface 50 can conduct a self-test on a logic circuit such as the ECC unit 4 by using a scan test, in accordance with a control signal such as the chip enable signal (CEn).

The self-test interface 50 generates the chip enable signal (CEn) for activating the NAND flash memory 1, the write enable signal (WEn), a command latch enable signal (CLEn), an address latch enable signal (ALEn), a read enable signal (REn), and an address (Address) in accordance with a test signal input from an external tester, and inputs these signals to the NAND sequencer 16. These control signals are used to control the NAND sequencer 16, and practically equivalent to the control signals issued by the NAND address/command generator 31 (to be described later).

Also, the self-test interface 50 stores those test patterns, which are input from an external tester via the serial data input/output pin (SIO), in the page buffer 13 via a data bus (Data Input/Output Bus). Similarly, the self-test interface 50 reads out data stored in the page buffer 13 via the data bus (Data Input/Output Bus), and outputs the readout data to the external tester via the serial data input/output pin (SIO).

The self-test interface 50 is installed in the RAM (buffer unit) 2 as an example, but the present invention is not limited to this. For example, the self-test interface 50 may also be installed in the NAND flash memory (main memory) 1 or controller 3, or independently installed. Furthermore, the self-test interface 50 may also be configured to be able to issue signals for controlling those individual circuits (e.g., an ECC buffer 40 and the SRAM buffer 26) in the buffer unit 2, which are required in the self-test including both (i) the test of write and read with respect to the SRAM memory cell array 21, and (ii) the test of data transfer between the page buffer 13 and the SRAM memory cell array 21.

### Arrangement of ECC Unit 4

The ECC unit 4 includes the ECC buffer 40, an ECC controller 41, a parity syndrome 42, and an error position decoder 44. As will be described later in the second embodiment, the self-test (BIST) of the ECC unit 4 is conducted by the scan test of the logic circuit via the self-test interface (BIST I/F) 50.

The ECC buffer (ECC Buffer) 40 is positioned between the SRAM buffer (SRAM Buffer) 26 and the page buffer 13 in the NAND flash memory 1, and temporarily stores data for ECC processing (error correction in data loading, and parity generation in data programming).

In accordance with an address and timing received from an SRAM address/timing generator 34, the ECC controller (ECC Control) 41 controls the parity syndrome 42 so as to control the data input/output of the ECC buffer 40 and the generation timing of a parity or syndrome.

In data programming, the parity syndrome (Parity Syndrome) 42 generates a parity by receiving ECC processing data (Data) from the ECC buffer 40 under the control of the ECC controller 41. In data loading, the parity syndrome 42 generates a syndrome by receiving ECC processing data (Data) and a parity from the ECC buffer 40 under the control of the ECC controller 41.

The error position decoder (Error Position Dec.) 44 receives the syndrome from the parity syndrome 42, and outputs the address (Correct) of a bit having a data error to the ECC buffer 40.

Note that the ECC unit 4 is incorporated into the RAM (buffer unit) 2 in this embodiment, but the present invention is not limited to this configuration. For example, the ECC unit 4 may also be incorporated into the NAND flash memory (main memory) 1 or the like, or independently installed.

Note also that when conducting the self-test including both (i) the test of write and read with respect to the SRAM memory cell array 21 and (ii) the test of data transfer between the page buffer 13 and the SRAM memory cell array 21, the self-test interface 50 or main state machine 32 controls the ECC unit 4 so as to activate at least the ECC buffer 40. That is, circuit operations related to error correction are unnecessary in the self-test including items (i) and (ii) described above, so the ECC controller 41, parity syndrome 42, and error position decoder 44 need not be activated.

### Arrangement of Controller 3

The controller 3 includes the NAND address/command generator 31, the main state machine (second controller) 32, the SRAM address/timing generator 34, a register 35, and a command user interface 36.

In an internal sequence operation controlled by the main state machine 32, the NAND address/command generator (NAND Add/Command Generator) 31 issues control signals (NAND I/F Command) such as an address and command for the NAND sequencer 16 as needed. The NAND address/command generator 31 issues the address, command, and the like in accordance with the external interface standards of the NAND flash memory 1.

For example, the NAND address/command generator 31 issues the above-mentioned chip enable signal (CEn), write enable signal (WEn), command latch enable signal (CLEn), address latch enable signal (ALEn), and read enable signal (REn). Also, the NAND address/command generator 31 transfers the address and command to the NAND flash memory 1.

In synchronism with the internal clock (Clock) from the oscillator 18, the main state machine (Main State Machine) 32 controls, e.g., the issue of the control signal (NAND I/F Command) (to be described later) generated by the NAND address/command generator 31.

Also, in the self-test (to be described later) including both (i) the test of write and read with respect to the SRAM memory cell array 21 and (ii) the test of data transfer between the page buffer 13 and the SRAM memory cell array 21, the main state machine 32 activates itself by receiving the BIST test command signal issued by the NAND sequencer 16. The main state machine 32 has a function (logic) of executing data transfer between the page buffer 13 and the SRAM memory cell array 21 in accordance with the BIST test command signal.

The SRAM address/timing generator (SRAM Add/Timing) 34 generates control signals such as an address and timing for the SRAM 2 as needed in the internal sequence operation controlled by the main state machine 32.

The register (Register) 35 sets the operating state of a function. A part of the external address space is allocated to the register 35, and commands and the like externally transmitted via the user interface 29 are held in the register 35.

When predetermined data is written in the register (Register) 35, the command user interface (CUI) 36 detects that a function execution command is given, and issues an internal command signal (Command).

In the semiconductor memory device according to this embodiment, the NAND flash memory 1 functions as a main memory, and the SRAM 2 functions as a buffer unit of the main memory. When reading out data outside from the NAND flash memory 1, therefore, data read out from the memory cell array 11 of the NAND flash memory 1 is first stored in the SRAM memory cell array 21 via the page buffer 13. After that, the data in the SRAM memory cell array 21 is transferred to the user interface 29, and output outside.

On the other hand, when storing data in the NAND flash memory 1, externally given data is first stored in the SRAM memory cell array 21 via the user interface 29. After that, the data in the SRAM memory cell array 21 is transferred to the page buffer 13, and written in the memory cell array 11.

In this specification, therefore, the operation of reading out data from the memory cell array 11 and transferring the data to the SRAM memory cell array 21 via the page buffer 13 will be called “load (Load)” of data. Also, the operation of transferring the data in the SRAM memory cell array 21 to the user interface 29 via the burst read/write buffer 28 in the user interface 29 will be called “read (Read)” of data. “Load” and “Read” will collectively be called a “read function operation”, and the details will be described later.

In addition, the operation of transferring data to be stored in the NAND flash memory 1 from the user interface 29 to the SRAM memory cell array 21 via the burst read/write buffer 28 will be called “write (Write)” of data. Furthermore, the operation of transferring the data in the SRAM memory cell array 21 to the page buffer 13 and writing the data in the memory cell array 11 of the NAND flash memory 1 will be called “programming (Program)” of data. “Write” and “Program” will collectively be called a “write function operation”, and the details will be described later.

### 1-2. Configuration Example of NAND Block

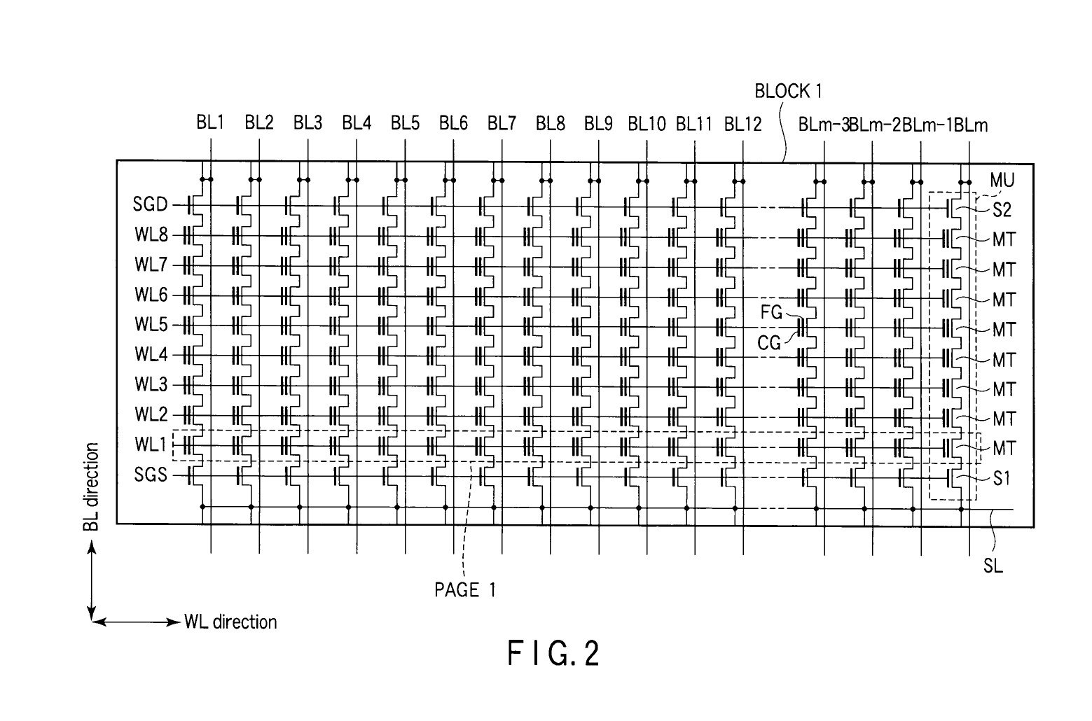

A configuration example of the block (BLOCK) forming the cell array 11 shown in FIG. 1 will be explained below with reference to FIG. 2.

The explanation will be made by taking a block BLOCK 1 as an example. Note that data of memory cell transistors in the block BLOCK 1 are collectively erased. That is, the block is an erase unit.

As shown in FIG. 2, the block BLOCK 1 includes a plurality of memory cell columns (memory cell units) MU arranged in the word line direction (WL direction). The memory cell column MU includes a NAND string including eight memory cell transistors MT whose current paths are connected in series, a selection transistor S1 connected to one end of the NAND string, and a selection transistor S2 connected to the other end of the NAND string.

Note that the NAND string includes the eight memory cell transistors MT in this example, but the NAND string need only include two or more memory cells, so the number of memory cell transistors is not particularly limited to 8.

The other end of the current path of the selection transistor S2 is connected to a bit line BLm. The other end of the current path of the selection transistor S1 is connected to a source line SL.

Word lines WL1 to WL8 run in the WL direction, and are each connected to a plurality of memory cell transistors in the WL direction. A select gate line SGD runs in the WL direction, and is connected to a plurality of selection transistors S2 in the WL direction. Also, a select gate line SGS runs in the WL direction, and is connected to a plurality of selection transistors S1 in the WL direction.

The word lines WL1 to WL8 each form a unit called a page (PAGE). For example, page 1 (PAGE 1) is allocated to the word line WL1 as indicated by the broken lines in FIG. 2. Since a read operation and write operation are performed page by page, the page is a read unit and write unit. Note that when using multilevel memory cells each capable of holding data having a plurality of bits, a plurality of pages are allocated to one word line.

Each memory cell MT is formed at the intersection of the bit line BL and word line WL, and has a stacked structure in which a tunnel insulating film, a floating electrode FG as a charge storage layer, an inter-gate insulating film, and a control electrode CG are sequentially formed on a semiconductor substrate. The source and drain forming the current path of the memory cell MT are connected in series to the source and drain of adjacent memory cells MT. One end of the current path is connected to the bit line BLm via the selection transistor S2. The other end of the current path is connected to the source line SL via the selection transistor S1.

Also, each memory cell MT includes spacers formed along the sidewalls of the stacked structure, and the source and drain formed in the semiconductor substrate (Si substrate (Si-sub) or P-well) so as to sandwich the stacked structure.

The selection transistors S1 and S2 each include a gate insulating film, inter-gate insulating film, and gate electrode. The inter-gate insulating film of each of the selection transistors S1 and S2 is separated from the center, so that layers above and below the inter-gate insulating film are electrically connected. Similarly, the selection transistors S1 and S2 each include spacers formed along the sidewalls of the gate electrode, and the source and drain formed in the semiconductor substrate so as to sandwich the gate electrode.

### 2. Read Function Operation

The read function operation of the semiconductor memory device according to the first embodiment will be explained below. As described previously, the read function operation is a combination of the aforementioned “Load” and “Read” operations.

Data “Load” is the operation of reading out data from the memory cell array 11 of the NAND flash memory 1, and transferring the readout data to the SRAM memory cell array 21 via the page buffer 13. Data “Read” is the operation of transferring the data in the SRAM memory cell array 21 to the user interface 29 via the burst read/write buffer 28 in the user interface 29.

### 2-1. “Load”

(1-1) First, the user sets the NAND address and SRAM address of loading in the register (Register) 35 from the host apparatus through the user interface (User I/F) 29.

(1-2) Subsequently, the user sets a load command in the register (Register) 35 from the host apparatus through the user interface (User I/F) 29. When the command is written in the register 35, the command user interface (CUI) 36 detects that the command is written, and generates an internal command signal (Command). This establishes the load command.

(1-3) In response to the establishment of the load command, the main state machine (Main State Machine) 32 activates itself.

(1-4) The main state machine 32 performs necessary circuit initialization, and requests the NAND address/command generator (NAND Add/Command Generator) 31 to issue a sense command of the NAND flash memory 1.

(1-5) The NAND address/command generator 31 issues the sense command to the NAND sequencer (NAND Sequencer) 16 so as to sense the NAND address set in the register 35.

(1-6) In response to the sense command, the NAND sequencer 16 activates itself.

(1-7) The NAND sequencer 16 performs necessary circuit initialization, and controls the voltage supply circuit (Voltage Supply) 15, row decoder (Row Decoder) 14, sense amplifier (S/A) 12, and page buffer (Page Buffer) 13 in order to perform the operation of sensing the designated address, thereby saving the sense data in the page buffer 13.

(1-8) The NAND sequencer (NAND sequencer) 16 then notifies the main state machine 32 that the sense operation of the NAND flash memory 1 is complete.

(1-9) The main state machine 32 requests the NAND address/command generator 31 to issue a read command of the NAND flash memory 1.

(1-10) In response to the read command, the NAND sequencer 16 sets the page buffer 13 in a readable state.

(1-11) The main state machine 32 issues a read command (clock) to the NAND sequencer (NAND Sequencer) 16, reads out data from the page buffer (Page Buffer) 13 to the NAND data bus (NAND Data Bus), and transfers the readout data to the ECC buffer (ECC Buffer) 40.

(1-12) The main state machine 32 controls the ECC controller 41 to issue an ECC correction start control signal to the parity syndrome (Parity Syndrome) circuit 42.

(1-13) The parity syndrome (Parity Syndrome) circuit 42 generates a syndrome, and the error position decoder (Error Position Decoder) 44 determines a data error position based on the syndrome, and inverts the data error.

(1-14) The error-corrected data is read out to the ECC data bus, and transferred to the SRAM buffer (SRAM Buffer) 40.

(1-15) Subsequently, the data is written in the SRAM memory cell array (SRAM Cell Array) 21, and the “Load” operation is terminated.

### 2-2. “Read”

(1-16) After that, data “read (Read)” is performed. That is, the data in the SRAM memory cell array 21 is transferred to the user interface (User I/F) 29 via the burst read/write buffer 28.

Consequently, the external user can read out the data in the SRAM memory cell array 21 outside through the user interface (User I/F) 29.

### 3. Write Function Operation

The write function operation of the semiconductor memory device according to the first embodiment will be explained below. As described previously, the write function operation is a combination of the aforementioned “Write” and “Program” operations.

Data “Write” is the operation of transferring data to be stored in the NAND flash memory 1 from the user interface 29 to the SRAM memory cell array 21 via the burst read/write buffer 28. Data “Program” is the operation of transferring the data in the SRAM memory cell array 21 to the page buffer 13, and writing the data in the memory cell array 11 of the NAND flash memory 1.

### 3-1. “Write”

(2-1) First, the host apparatus that executes user's instructions writes data to be programmed in the SRAM memory cell array 21 in the RAM 2 through the user interface (User I/F) 29.

### 3-2. “Program”

(2-2) Then, the host apparatus that executes user's instructions sets the NAND address and SRAM address of programming in the register (Register) 35 through the user interface (User I/F) 29.

(2-3) Subsequently, the host apparatus that executes user's instructions sets a program command in the register (Register) 35 through the user interface (User I/F) 29. When the command is written in the register 35, the command user interface (CUI) 36 detects that the command is written, and generates an internal command signal (Command). This establishes the program command.

(2-4) In response to the establishment of the program command, the main state machine (Main State Machine) 32 activates itself.

(2-5) The main state machine 32 performs necessary circuit initialization, and requests the NAND address/command generator (NAND Add/Command Generator) 31 to issue a page buffer load command of the NAND flash memory 1.

(2-6) The main state machine 32 then issues a read clock to the RAM 2, reads out data in the RAM 2 to the ECC bus (ECC Bus), and transfers the readout data to the ECC buffer (ECC Buffer) 40.

(2-7) Subsequently, the main state machine 32 performs control to issue an ECC parity generation start control signal.

(2-8) The parity syndrome circuit (Parity Syndrome) 42 generates a syndrome, generates parity data based on the syndrome, and writes the parity data in the ECC buffer (ECC Buffer) 40.

(2-9) The main state machine 32 reads out, to the NAND data bus, the data to which the parity data is added, and transfers the readout data to the NAND page buffer (NAND Page Buffer) 13.

(2-10) The NAND address/command generator (NAND Add/Command Generator) 31 issues a program command to the NAND sequencer (NAND Sequencer) 16 so as to program the data in the NAND address set in the register 35.

(2-11) The NAND sequencer 16 performs necessary circuit initialization in response to the program command, and controls the voltage supply circuit (Voltage Supply) 15, row decoder (Row Decoder) 14, sense amplifier (S/A) 12, and page buffer (Page Buffer) 13 in order to perform the programming operation at the designated address, thereby programming the data in the NAND cell array 11.

(2-12) The NAND sequencer 16 then notifies the main state machine 32 that the programming of the NAND cell array 11 is complete.

(2-13) Subsequently, the user sets, e.g., a status for monitoring, thereby terminating the operation.

### 4. Self-Test Operation

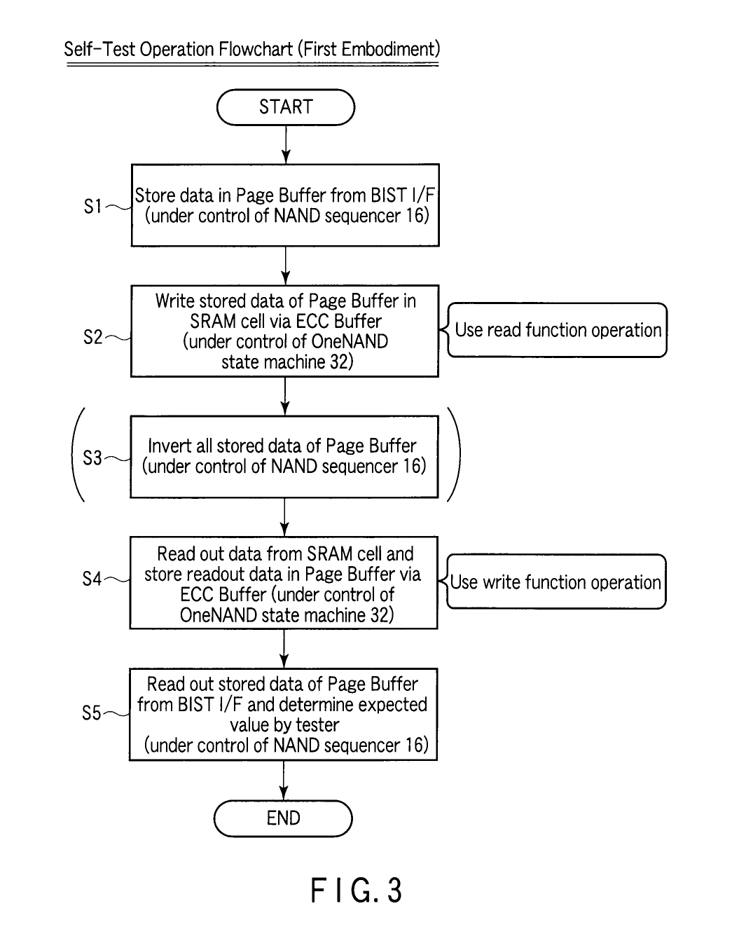

The self-test operation (the self-test including both (i) the test of write and read with respect to the SRAM memory cell array 21 and (ii) the test of data transfer between the page buffer 13 and the SRAM memory cell array 21) of the semiconductor memory device according to the first embodiment will now be explained with reference to a flowchart shown in FIG. 3. Note that in this embodiment, the explanation of details of a self-test such as a write or read test normally performed on the NAND flash memory 1 will be omitted.

### (Step S1)

A test pattern is stored in the page buffer 13 via the self-test interface (BIST I/F) 50 under the control of the NAND sequencer 16. More specifically, the test pattern is first input from an external tester via the serial data input/output pin (SIO). Subsequently, the self-test interface 50 issues a control signal and command to the NAND sequencer 16, thereby storing the test pattern in the page buffer 13 via the data bus

### (Data Input/Output Bus).

### (Step S2)

The data of one page stored in the page buffer 13 is transferred to the SRAM buffer 26 via the ECC buffer 40, and written in the SRAM memory cell array 21 via the SRAM buffer 26, under the control of the main state machine 32.

Step S2 uses 2. Read Function Operation described above. More specifically, step S2 uses a part of 2-1. “Load”. That is, when the self-test interface 50 issues a command of this test operation, the NAND sequencer 16 issues a BIST test command signal (BIST Command) to the main state machine 32, thereby activating the main state machine 32, and transferring the data from the page buffer 13 to the SRAM memory cell array 21.

In 2. Read Function Operation described previously, data in the NAND cell array 11 is sensed by the sense amplifier 12, stored in the page buffer 13, and transferred to the RAM 2. In step S2, however, data prestored in the page buffer 13 is transferred to the RAM 2 and written in the SRAM memory cell array 21 without sensing any data in the NAND memory cell array 11.

### (Step S3)

All the data stored in the page buffer 13 are inverted under the control of the NAND sequencer 16. For example, when all the stored data are data “1” (all “1”s), the stored data of the page buffer 13 are inverted into data “0” (all “0”s)

Note that step S3 is not always essential in this self-test. However, a stricter test is conducted by inverting data in step S3, so step S3 is advantageous in that the test accuracy can be increased. It is also possible to clear (erase) all the stored data of the page buffer 13 as needed.

### (Step S4)

The data stored in the SRAM memory cell array 21 is read out, transferred to the ECC buffer 40 via the SRAM buffer 26, and stored in the page buffer 13 via the ECC buffer 40, under the control of the main state machine 32.

Step S4 uses 3. Write Function Operation described above. More specifically, step S4 uses a part of 3-1. “Program”. That is, when the self-test interface 50 issues the command of step S4, the NAND sequencer 16 issues the BIST test command signal (BIST Command) to the main state machine 32, thereby activating the main state machine 32. Subsequently, the data is transferred from the SRAM memory cell array 21 to the page buffer 13.

In 3. Write Function Operation described earlier, data in the SRAM memory cell array 21 is read out, transferred to the page buffer, and written in the NAND memory cell array 11. In step S4, however, the data is transferred from the SRAM memory cell array 21 to the page buffer 13, but is not written in the NAND memory cell array 11.

### (Step S5)

The data stored in the page buffer 13 is read out via the self-test interface 50, and compared with an expected value (the initially input test pattern) by the external tester, under the control of the NAND sequencer 16. More specifically, the self-test interface 50 issues a control signal and command to the NAND sequencer 16, thereby outputting the data stored in the page buffer 13 to the external tester via the data bus (Data Input/Output Bus) and serial data input/output pin (SIO). Subsequently, the external tester compares the expected value held by the external tester with the data output via the data bus, and checks whether the two values match.

The series of operations in steps S1 to S5 explained above are executed by data input from the self-test interface 50 including the data input/output pin (SIO). In the wafer probing test in the form of the BIST, therefore, it is possible to conduct the self-test including both (i) the test of write and read with respect to the SRAM memory cell array 21 and (ii) the test of data transfer between the page buffer 13 and the SRAM memory cell array 21, in the same test environment as that of the NAND flash memory (main memory) 1.

In a system product including a NAND flash memory, a test including data transfer between the NAND flash memory and another circuit block is generally conducted after packaging in many cases. In this embodiment, however, the test can be conducted on the wafer by using the same self-test interface as that of the self-test of the NAND flash memory 1. Accordingly, it is unnecessary to construct different test environments between the RAM (buffer unit) 2 and the NAND flash memory (main memory) 1. This is advantageous in reducing the test cost.

Also, random data can be input and output via the self-test interface 50. This makes it possible to conduct, e.g., a screening test by taking account of the bit layout and address scramble in the SRAM memory cell array 21, and a screening test by taking account of the data bus array between the page buffer 13 and the SRAM memory cell array 21.

### 5. Effects

As described above, the semiconductor memory device and the self-test method of the same according to the first embodiment achieve at least the effects of items (1) and (2) below.

(1) The test cost is advantageously reduced.

As described above, the semiconductor memory device according to this embodiment includes the main memory 1, the buffer unit 2 of the main memory 1, and the controller 3. The main memory 1 includes the nonvolatile memory 11, and the buffer 13 for storing input/output data of the nonvolatile memory. The buffer unit 2 includes the volatile memory 21, and the self-test interface 50 including the data input/output pin. The controller 3 controls the main memory 1 and buffer unit 2. In addition, the controller 3 stores data in the buffer 13 from the self-test interface 50 via the data input/output pin (S1), writes the stored data of the buffer 13 in the volatile memory 21 (S2), (inverts all the stored data of the buffer 13 (S3)), stores the data read out from the volatile memory 21 in the buffer 13, reads out the stored data of the buffer 13 from the self-test interface 50, and performs determination.

The series of operations in steps S1 to S5 described above are executed by issuing commands from the self-test interface 50. In the wafer probing test in the form of the BIST, therefore, it is possible to conduct the self-test including both (i) the test of write and read with respect to the SRAM memory cell array 21 and (ii) the test of data transfer between the page buffer 13 and the SRAM memory cell array 21, in the same test environment as that of the NAND flash memory (main memory) 1.

Accordingly, it is unnecessary to construct different test environments between the RAM (buffer unit) 2 and the NAND flash memory (main memory) 1. This is advantageous in reducing the test cost. Also, this embodiment can detect the percent defectives of (i) the buffer unit 2 and (ii) its data transfer path in the test step in the wafer stage before packaging.

Also, random data can be input and output via the self-test interface 50. This makes it possible to conduct, e.g., a screening test by taking account of the bit layout and address scramble in the SRAM memory cell array 21, and a screening test by taking account of the data bus array between the page buffer 13 and the SRAM memory cell array 21.

Note that step S3 is not always essential in the self-test according to this embodiment. However, a stricter test is conducted by inverting data in step S3, so step S3 is advantageous in that the test accuracy can be increased.

(2) The test time is advantageously shortened.

As described in item (1) above, in the wafer probing test in the form of the BIST, the arrangement and the self-test method of the same according to this embodiment can conduct the self-test including both (i) the test of write and read with respect to the SRAM memory cell array 21 and (ii) the test of data transfer between the page buffer 13 and the SRAM memory cell array 21, in the same test environment as that of the NAND flash memory (main memory) 1.

Thus, the self-tests of the RAM 2 and NAND flash memory 1 are conducted in the same test step. Since different test environments need not be constructed, the test time is advantageously shortened.

Also, the number of test pins necessary for the self-test in the wafer stage is in many cases smaller than that necessary for the test after packaging. If the same test items can be performed in the wafer stage, therefore, larger simultaneous measurement numbers are obtained, and this leads to the reduction in test time. This embodiment uses parts of the read function operation and write function operation used in the normal operation sequence of the semiconductor memory device. This makes it possible to conduct the data transfer test between the RAM 2 and the NAND flash memory 1 by using the same self-test interface as that of the self-test, which is executed using a small number of test pins, of the NAND flash memory 1. This is advantageous in shortening the test time.

### Second Embodiment

### Example Using Common Input/Output Pin

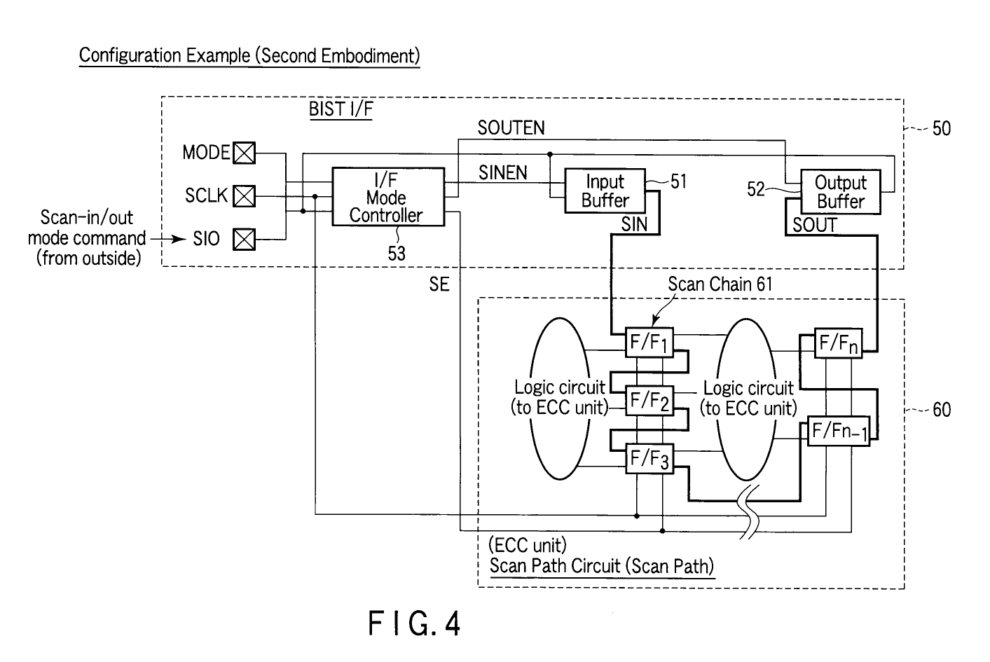

A semiconductor memory device and a self-test method of the same according to the second embodiment will be explained below with reference to FIGS. 4 to 6. This embodiment is directed to an example in which the self-test of a logic circuit such as an ECC unit 4 is conducted by using a common input/output pin of a self-test interface 50. In the following description, a repetitive explanation of the same portions as in the first embodiment will be omitted.

### <Configuration Example of Scan Test Circuit>

First, a configuration example of the semiconductor memory device according to the second embodiment will be explained with reference to FIG. 4. As shown in FIG. 4, the semiconductor memory device according to this embodiment differs from the first embodiment in that the device includes a scan test (Scan Test) circuit.

The scan test circuit includes the above-mentioned, self-test interface 50 including an input buffer 51, output buffer 52, and mode controller 53, and a scan path circuit 60.

The input buffer (Input Buffer) 51 has an input connected to a serial data input/output pin (SIO), and an output (SIN) connected to the scan path circuit 60. The operation of the input buffer 51 is controlled in accordance with a control signal (SINEN) from the mode controller.

The output buffer (Output Buffer) 52 has an input (SOUT) connected to the output of the scan path circuit 60, and an output connected to the serial data input/output pin (SIO). The operation of the output buffer 52 is controlled in accordance with a control signal (SOUTEN) from the mode controller.

The mode controller (I/F Mode Controller) 53 has an input connected to a mode signal pin (MODE), a clock pin (SCLK), and the serial data input/output pin (SIO). In accordance with a scan-in/out mode command input from the serial data input/output pin (SIO), the mode controller 53 selectively outputs the control signals (SINEN and SOUTEN) to the input buffer 51 and output buffer 52.

Accordingly, the input buffer 51 and output buffer 52 are respectively activated by an input buffer enable signal (SINEN) and output buffer enable signal (SOUTEN). When the input buffer enable signal (SINEN) is activated, the scan data input signal SIN accepts input data from the serial data input/output pin (SIO). When the output buffer enable signal (SOUTEN) is activated, the serial data input/output pin (SIO) accepts output data from the scan data output signal SOUT.

The self-test interface 50 includes three terminals, i.e., the mode signal pin (MODE), clock pin (SCLK), and serial data input/output pin (SIO), all of which are connected to external terminals. The three terminals can also be used when executing the wafer probing test of a NAND flash memory 1, and executing the self-test according to the above-described first embodiment in the wafer probing test.

When performing a scan test in an arrangement according to a comparative example (to be described later), a scan data input pin (SIN) and scan data output pin (SOUT) are independently connected to external pins. Generally, an arrangement in which the scan data input pin (SIN) and scan data output pin (SOUT) are separated as in the arrangement according to the comparative example is often adopted owing to the restrictions on an automatic scan test pattern generation tool.

In the arrangement according to the second embodiment, however, the serial data input/output pin (SIO) is used as a common terminal by respectively controlling the scan data input signal and scan data output signal via the input buffer 51 and output buffer 52.

The scan path circuit 60 performs parallel/serial conversion on data exchanged between the self-test interface 50 and a logic circuit (in this embodiment, the ECC unit 4), in accordance with a control signal (SE) from the mode controller 53. The scan path circuit 60 includes a scan chain (Scan Chain) circuit 61. Note that in this embodiment, the scan path circuit 60 is installed in the ECC unit 4.

The scan chain (Scan Chain) circuit 61 includes a plurality of flip-flop circuits (F/F₁ to F/Fₙ).

The inputs and outputs of the flip-flop circuits (F/F₁ to F/Fₙ) are connected in series in the form of a chain between the output (SIN) of the input buffer 51 and the input (SOUT) of the output buffer 52. In accordance with the control signal (SE) input from the mode controller 53, the flip-flop circuits (F/F₁ to F/Fₙ) convert held data into parallel data, and outputs the converted data to the logic circuit (in this embodiment, the ECC unit 4). Also, in accordance with the control signal (SE) input from the mode controller 53, the flip-flop circuits (F/F₁ to F/Fₙ) hold parallel data input from the logic circuit (ECC unit 4), convert the held data into serial data, and output the converted data to the input buffer 52.

Note that this embodiment has been explained by taking, for example, the arrangement in which the self-test interface 50 incorporates the input buffer 51, output buffer 52, and mode controller 53 of the scan test circuit. However, the present invention is not limited to this arrangement.

### <Scan Test Operation of Logic Circuit>

The scan test operation of the semiconductor memory device according to the second embodiment will be explained below.

### Scan-In Mode

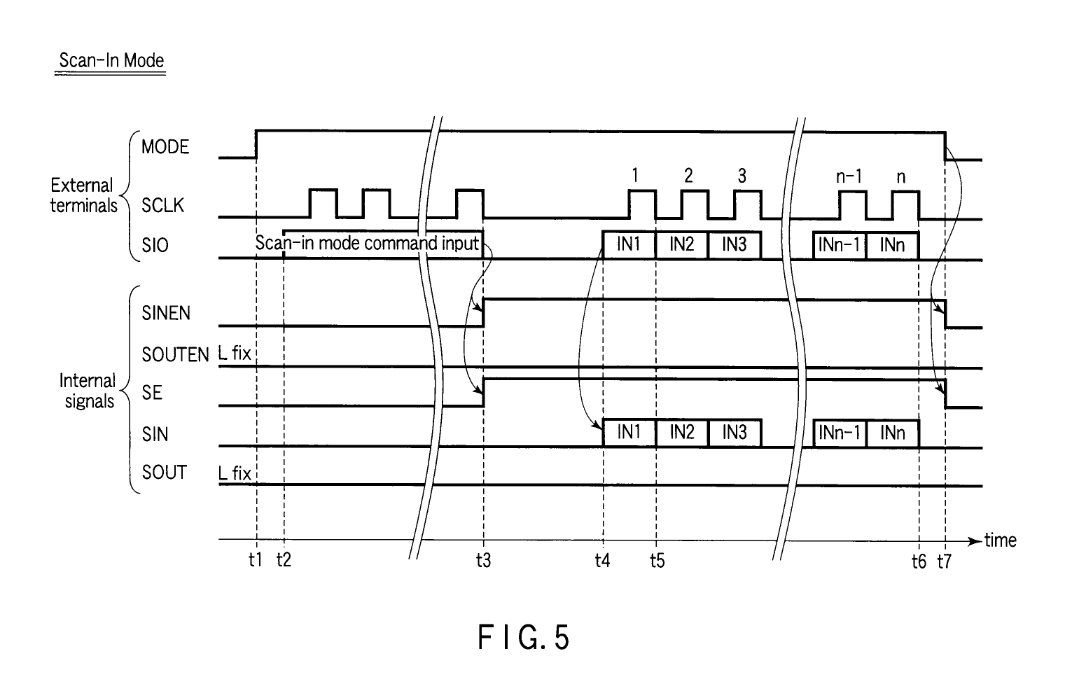

First, a scan-in mode will be explained with reference to a timing chart shown in FIG. 5. Note that the internal signals SOUTEN and SOUT are fixed at level “L” (Lfix) in this scan-in mode.

First, at time t1, the mode entry signal MODE input from the mode signal pin is changed to level “H” as the level of a power supply voltage Vdd, thereby activating the mode controller 53.

Subsequently, at time t2, the scan-in mode command is input from the serial data input/output pin (SIO) to the self-test interface 50.

At time t3, the scan-in mode command is loaded into the circuit in synchronism with the serial clock signal SCLK, thereby activating the scan enable signal SE and input buffer enable signal SINEN (to level “H”).

During times t4 to t6, scan test pattern data (IN1, IN2, IN3, . . . , INn−1, and INn) input from the serial data input/output pin (SIO) in synchronism with the serial clock signal SCLK (1, 2, 3, . . . , n−1, and n) are sequentially stored, as they are shifted, in all registers of the flip-flops (F/F₁ to F/Fₙ) forming the scan chain circuit 61 via the scan data input SIN.

At time t7, the mode entry signal MODE input from the mode signal pin is changed to level “L” as the level of a ground power supply voltage Vss, thereby changing the internal signals SINTEN and SE to level “L”, and terminating the scan-in mode.

### Scan-Out Mode

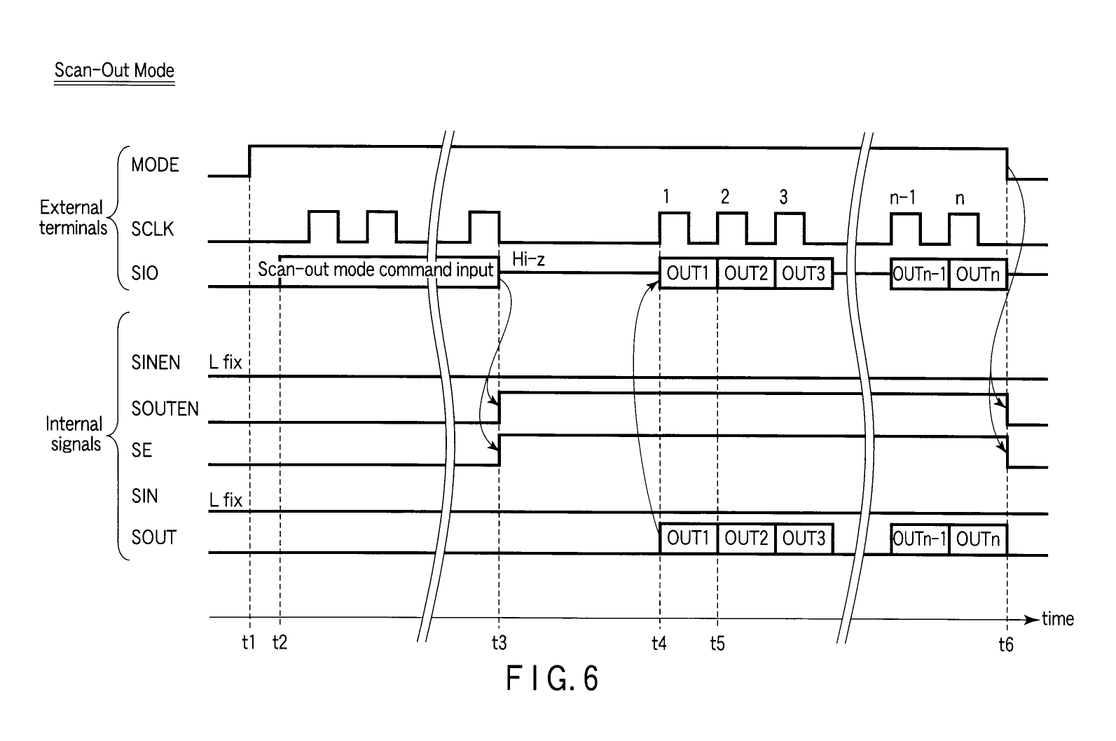

A scan-out mode will now be explained with reference to a timing chart shown in FIG. 6. Note that the internal signals SINEN and SIN are fixed at level “L” (Lfix) in this scan-out mode.

First, at time t1, the mode entry signal MODE input from the mode signal pin is changed to level “H” as the power supply voltage Vdd level, thereby activating the mode controller 53.

Subsequently, at time t2, the scan-out mode command is input from the serial data input/output pin (SIO) to the self-test interface 50.

At time t3, the scan-out mode command is loaded into the circuit in synchronism with the serial clock signal SCLK, thereby activating the scan enable signal SE and input buffer enable signal SINEN (to level “H”). After time t3, the level of the serial data input/output pin (SIO) is set at “Hi−z”.

During times t4 to t6, in synchronism with the continuous amplitude (1, 2, 3, . . . , n−1, and n) of the serial clock signal SCLK, scan test pattern data (OUT1, OUT2, OUT3, . . . , OUTn−1, and OUTn) are sequentially read out, as they are shifted, from all the registers of the flip-flops (F/F₁ to F/Fₙ) forming the scan chain circuit 61 to the serial data input/output pin (SIO) via the scan data output SOUT.

In addition, at time t6, the mode entry signal MODE input from the mode signal pin is changed to level “L” as the ground power supply voltage Vss level, thereby changing the internal signals SOUTEN and SE to level “L”, and terminating the scan-out mode.

### <Effects>

As described above, the semiconductor memory device and the self-test method of the same according to the second embodiment achieve at least the same effects as those of items (1) and (2) described earlier. The reasons why the same effects as those of items (1) and (2) are obtained will be explained below.

(1) The test cost is advantageously reduced.

The self-test interface 50 according to the second embodiment includes the input buffer 51 for storing the scan input data of the logic circuit 4, the output buffer 52 for storing the scan output data of the logic circuit 4, and the mode controller 53 for controlling the self-test of the logic circuit 4 by switching the scan input and scan output of the input buffer 51 and output buffer 52 in accordance with the switching command (SE) input to the serial data input/output pin (SIO).

The above-mentioned arrangement and test operation adopt the serial data input/output pin (SIO) capable of bidirectionally inputting and outputting the scan data input signal SIN and scan data output signal SOUT in the scan test. This makes it possible to use a common terminal as the scan data input pin (SIN) and scan data output pin (SOUT).

In the wafer probing test of a large-capacity memory such as the NAND flash memory (main memory) 1, a self-test is often conducted by using the serial data input/output pin (SIO). In this embodiment, a test pin to be used for data input/output in the scan test of a logic circuit such as the ECC unit 4 is the same serial data input/output pin (SIO) as that used for the wafer probing test of the NAND flash memory 1. Since this facilitates using a common test pin, the same test environment can be used. This is advantageous in reducing the test cost. Note that as in the first embodiment, a self-test including both (i) a test of write and read with respect to an SRAM memory cell array 21 and (ii) a test of data transfer between a page buffer 13 and the SRAM memory cell array 21 can also be conducted in the same test environment.

(2) The test time is advantageously shortened.

This embodiment adopts the serial data input/output pin (SIO) capable of bidirectionally inputting and outputting the scan data input signal SIN and scan data output signal SOUT in the scan test. This makes it possible to use a common terminal as the scan data input pin (SIN) and scan data output pin (SOUT).

Accordingly, the number of probes (the number of test pins) for probing per chip can be reduced when performing the wafer probing test. In the second embodiment, for example, the test can be performed using only three pins (the mode signal pin (MODE), clock pin (SCLK), and serial data input/output pin (SIO)); the number of pins can be made smaller by one than that of the comparative example (to be described later). Since this facilitates constructing the test environment of, e.g., a batch test of all chips in a wafer, the test time is advantageously shortened.

Furthermore, this embodiment achieves the effect of item (3) below.

(3) The reliability can be improved because a scan test can be conducted on the logic circuit (ECC unit 4).

Although this embodiment uses one common terminal (the serial data input/output pin (SIO)) as the scan data input pin (SIN) and scan data output pin (SOUT), a scan test can be conducted on the logic circuit (in this embodiment, the ECC unit 4) by executing the test operation by switching the scan-in mode and scan-out mode in the self-test interface 50. Accordingly, the reliability of the semiconductor memory device can be improved.

In this embodiment as described above, the scan test pattern data is input and output by one terminal (SIO) as an external terminal for executing the scan test, so the same input/output terminal can be used for the serial test of the embedded memory. Therefore, the reliability can be improved because a batch scan test including the logic circuit (ECC unit 4) can be conducted in the same test environment.

Note that the ECC unit 4 is taken as an example of the logic circuit in the second embodiment, but the present invention is not limited to this. For example, the present invention is similarly applicable to a controller 30 including, e.g., a NAND sequencer 16 and main state machine 32, or another logic circuit installed in, e.g., the main memory 1 or RAM 2, and achieves the same effects.

### Comparative Example

### Example Using No Common Data Input/Output Pin

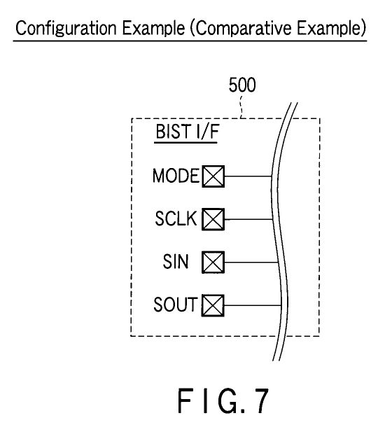

A semiconductor memory device according to the comparative example will be explained below with reference to FIG. 7. This comparative example is directed to an arrangement using no common data input/output pin in the self-test of a logic circuit. In the following description, a repetitive explanation of the same portions as those of the second embodiment will be omitted.

### Configuration Example

First, a configuration example of the semiconductor memory device according to the comparative example will be explained with reference to FIG. 7.

As shown in FIG. 7, a self-test interface 500 according to the comparative example differs from the second embodiment in that there is no common data input/output pin, and pins such as a data input pin (SIN) and data output pin (SOUT) are respectively arranged for data input and output.

That is, the number of probes (the number of pins) required for a test is at least four (a mode signal pin (MODE), clock pin (SCLK), serial data input pin (SIO), and serial data output pin (SOUT)); the number of pins is larger by one than that of the second embodiment.

Consequently, it is sometimes impossible to execute a batch test on all chips in a wafer. In this case, the test environment is hard to construct. Also, a test terminal for the wafer probing test of a NAND flash memory cannot be used as a test terminal for a logic circuit such as an ECC unit. This makes it difficult to construct the test environment, and makes a batch test impossible in some cases.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
a main memory unit comprising a nonvolatile memory, and a buffer which stores input/output data of the nonvolatile memory;
a buffer unit of the main memory, the buffer unit comprising a volatile memory;
a self-test interface comprising a data input/output pin; and
a controller which controls the main memory unit and the buffer unit,
wherein the controller stores data in the buffer from the self-test interface via the data input/output pin,
writes the stored data of the buffer in the volatile memory,
stores the data read out from the volatile memory in the buffer, and
reads out the stored data of the buffer from the self-test interface.

2. The device of claim 1, wherein the controller comprises a first controller which controls the main memory unit, and a second controller which controls at least data transfer between the main memory unit and the buffer unit, and
the first controller is configured to issue a test command signal to the second controller.

3. The device of claim 1, further comprising:
a logic circuit; and
a scan test circuit comprising an input buffer which stores scan input data of the logic circuit, an output buffer which stores scan output data of the logic circuit, and a controller which controls a self-test of the logic circuit by switching a scan input and a scan output of the input buffer and the output buffer in accordance with a switching command input to the data input/output pin.

4. The device of claim 3, wherein the logic circuit comprises an ECC circuit.

5. The device of claim 3, further comprising a scan path circuit which performs parallel/serial conversion on data exchanged between the self-test interface and the logic circuit, in accordance with a control signal from the controller.

6. The device of claim 5, wherein the scan path circuit comprises a scan chain circuit comprising flip-flop circuits connected in series in the form of a chain between an output of the input buffer and an input of the output buffer.

7. The device of claim 4, wherein the ECC circuit comprises:
an ECC buffer which is installed between the nonvolatile memory and the volatile memory, and temporarily stores ECC processing data;
a parity syndrome which generates a parity by receiving the ECC processing data input from the ECC buffer when programming is performed, and generates a syndrome by receiving the ECC processing data and the parity input from the ECC buffer when loading is performed;
an ECC control which controls the parity syndrome; and
an error position decoder which receives the syndrome input from the parity syndrome, and outputs an address of a bit having a data error to the ECC buffer.

8. The device of claim 1, wherein
the nonvolatile memory comprises a NAND flash memory comprising a plurality of blocks, and
the volatile memory comprises an SRAM.

9. The device of claim 8, wherein
the block comprises a memory cell unit comprising a plurality of memory cells arranged in a matrix at intersections of word lines and bit lines, a NAND string comprising a plurality of memory cells whose current paths are connected in series, a first selection transistor connected to one end of the NAND string, and a second selection transistor connected to the other end of the NAND string,
a current path of the first selection transistor is connected to one of a plurality of bit lines, and
a current path of the second selection transistor is connected to a source line.

10. A self-test method of a semiconductor memory device, comprising:
storing data in a buffer from a self-test interface via a data input/output pin;
writing the stored data of the buffer in a volatile memory;
storing the data read out from the volatile memory in the buffer;
reading out the stored data of the buffer from the self-test interface; and
comparing an expected value with the data output from the self-test interface.

11. The method of claim 10, further comprising inverting all the stored data of the buffer.

12. The method of claim 10, further comprising conducting a self-test of a logic circuit by distinguishing between a scan input and a scan output in accordance with a switching command input to the data input/output pin.

13. The method of claim 10, wherein the semiconductor memory device comprises:
a main memory comprising a nonvolatile memory, and a buffer which stores input/output data of the nonvolatile memory;
a buffer unit of the main memory, the buffer unit comprising a volatile memory;
a self-test interface comprising a data input/output pin; and
a controller which controls the main memory and the buffer unit.

14. The method of claim 13, wherein the controller comprises a first controller which controls the main memory, and a second controller which controls at least data transfer between the main memory and the buffer unit, and
the first controller is configured to issue a test command signal to the second controller.

15. The method of claim 13, wherein the device further comprises:
a logic circuit; and
a scan test circuit comprising an input buffer which stores scan input data of the logic circuit, an output buffer which stores scan output data of the logic circuit, and a controller which controls a self-test of the logic circuit by switching a scan input and a scan output of the input buffer and the output buffer in accordance with a switching command input to the data input/output pin.
